(19) United States
(12) Patent Application Publication
(10) Pub. No.: US 2010/0232624 A1
(43) Pub. Date: Sep. 16, 2010

(54) Method and System for Virtual Bass Enhancement

(75) Inventor: Chen Zhang, Tianjing (CN)

Correspondence Address: SILICON VALLEY PATENT AGENCY, 7394 WILDFLOWER WAY, CUPERTINO, CA, 95014, US

(73) Assignees: Vimicro Electronics Corporation, Tianjin (CN); Vimicro Corporation, Beijing (CN)

(21) Appl. No.: 12/605,183

(22) Filed: Oct. 23, 2009

(30) Foreign Application Priority Data
Mar. 13, 2009 (CN) 200910079938.6

(51) Int. Cl. H03G 5/00

(52) U.S. Cl. 381/103; 381/107

(57) ABSTRACT

Techniques for enhancing bass effects in an audio signal are described. According to one embodiment, an audio input signal is filtered to produce a low frequency component thereof (a low frequency signal of the audio input signal). The low frequency signal expressed in time domain is transformed to a corresponding spectrum expression in frequency domain. A fundamental frequency signal of the low frequency signal in the frequency domain is determined to generate a plurality of harmonics that are then transformed back to the time domain. Both the audio input signal (delayed) and the harmonics are synthesized to produce an audio output signal whose bass is greatly enhanced.

### BACKGROUND OF THE INVENTION

1. Field of the Invention

The present invention is related to audio signal processing, more particularly related to a method and a system for virtual bass enhancement.

2. Description of Related Art

A bass enhancement process is provided to enhance a low frequency component of audio signal. In general, both headphones and speakers have a low frequency loss to a certain degree. Thus bass effect has become one of important aspects to evaluate audio quality.

An EQ technique is a conventional bass enhancement method that amplifies energy of a low frequency component in a audio signal for bass enhancement. Peoples perceive or hear bass mainly depending on harmonics, but not a fundamental frequency. Even if the fundamental frequency is suppressed, people can still perceive or hear strong bass effect as long as the harmonics as well as the relationship between these harmonics still exists. Hence, a virtual bass enhancement technique is also provided to enhance the harmonics of the fundamental frequency of the bass for virtual bass enhancement.

The low frequency component may be attenuated considerably for the small headphones or speakers. Hence, it still can't achieve a satisfied bass enhancement sometimes even if the EQ technique is used. Additionally, the EQ technique may result in saturation noise. Generally, the harmonics of the low frequency signal are generated by feedback modulation in the conventional virtual bass enhancement technique, which may result in inter-modulation distortion noises.

Thus, improved techniques for method and system for virtual bass enhancement are desired to overcome the above disadvantages.

### SUMMARY OF THE INVENTION

This section is for the purpose of summarizing some aspects of the present invention and to briefly introduce some preferred embodiments. Simplifications or omissions in this section as well as in the abstract or the title of this description may be made to avoid obscuring the purpose of this section, the abstract and the title. Such simplifications or omissions are not intended to limit the scope of the present invention.

In general, the present invention is related to enhancing bass effects in an audio signal. According to one aspect of the present invention, a signal component(s) in low frequency is extracted to be enhanced separately. According to one embodiment, an audio input signal is filtered to produce a low frequency component thereof (a low frequency signal of the audio input signal). The low frequency signal expressed in time domain is transformed to a corresponding spectrum expression in frequency domain. A fundamental frequency signal of the low frequency signal in the frequency domain is determined to generate a plurality of harmonics that are then transformed back to the time domain. Both the audio input signal (delayed) and the harmonics are synthesized to produce an audio output signal whose bass is greatly enhanced.

Other objects, features, and advantages of the present invention will become apparent upon examining the following detailed description of an embodiment thereof, taken in conjunction with the attached drawings.

### BRIEF DESCRIPTION OF THE DRAWINGS

These and other features, aspects, and advantages of the present invention will become better understood with regard to the following description, appended claims, and accompanying drawings where:

FIG. 1 is a block diagram showing a system for virtual bass enhancement according to one embodiment of the present invention;

FIG. 2 is a diagram showing an example of a slope function according to one embodiment of the present invention; and

FIG. 3 is a flow chart showing a method for virtual bass enhancement according to one embodiment of the present invention.

### DETAILED DESCRIPTION OF THE INVENTION

The detailed description of the present invention is presented largely in terms of procedures, steps, logic blocks, processing, or other symbolic representations that directly or indirectly resemble the operations of devices or systems contemplated in the present invention. These descriptions and representations are typically used by those skilled in the art to most effectively convey the substance of their work to others skilled in the art.

Reference herein to “one embodiment” or “an embodiment” means that a particular feature, structure, or characteristic described in connection with the embodiment can be included in at least one embodiment of the invention. The appearances of the phrase “in one embodiment” in various places in the specification are not necessarily all referring to the same embodiment, nor are separate or alternative embodiments mutually exclusive of other embodiments. Further, the order of blocks in process flowcharts or diagrams or the use of sequence numbers representing one or more embodiments of the invention do not inherently indicate any particular order nor imply any limitations in the invention.

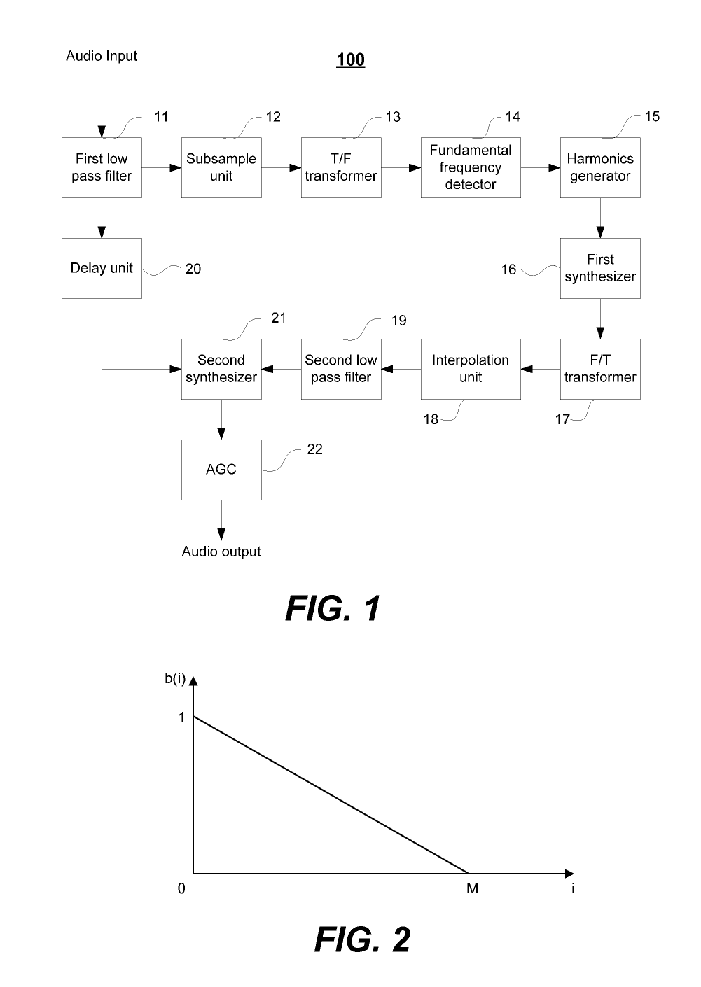

Embodiments of the present invention are discussed herein with reference to FIGS. 1-3. However, those skilled in the art will readily appreciate that the detailed description given herein with respect to these figures is for explanatory purposes only as the invention extends beyond these limited embodiments.

According to one embodiment of the present invention, one or more low frequency components from an audio input signal are extracted or filtered out. The low frequency components in a time domain are transformed to corresponding low frequency components in a frequency domain. A fundamental frequency signal of the low frequency components in the frequency domain is determined to generate a plurality of harmonics that are transformed from the frequency domain to corresponding harmonics in the time domain. The harmonics and the audio signal are synthesized to produce an output audio signal with bass enhanced. It is observed that the audio signals as processed do not introduce distortion or noises.

FIG. 1 is a block diagram showing a system 100 for virtual bass enhancement according to one embodiment of the present invention. The system 100 comprises a first low pass filter 11, a subsample unit 12, a time domain to frequency domain (T/F) transformer 13, a fundamental frequency detector 14, a harmonic generator 15, a first synthesizer 16, a frequency domain to time domain (F/T) transformer 17, an interpolation unit 18, a second low pass filter 19, a delay unit 20, a second synthesizer 21, and an automatic gain controller (AGO) 22.

The first low pass filter 11 is configured to filter out a portion of an audio input signal in low frequency according to a first cutoff frequency thereof to produce a low frequency component or signal of the audio input signal. As used herein, a low pass filter has a function of “low pass filtering”. The subsample unit 12 is configured to down-sample (or down sample) the low frequency signal by a down-sampling factor, denoted as M. The down-sampling factor M is usually an integer or a rational fraction larger than 1.

All signals before the T/F transformer 13 are in a time-domain. The T/F transformer 13 is configured to transform the down-sampled low frequency signal in the time domain into a corresponding down-sampled low frequency signal in a frequency domain. The fundamental frequency detector 14 is configured to analyze the down-sampled low frequency signal in the frequency domain to determine a fundamental frequency signal therein. The harmonic generator 15 is configured to generate a plurality of harmonics based on the fundamental frequency signal. The first synthesizer 16 is configured to synthesize the harmonics. All signals between the T/F transformer 13 and the F/T transformer 17 are in the frequency domain. The F/T transformer 17 is configured to transform the synthesized harmonics in the frequency domain into the synthesized harmonics in the time domain. All signals after the T/F transformer 13 are back in the time-domain.

The interpolation unit 18 is configured to interpolate the synthesized harmonics in the time domain by an interpolation factor thereof. The second low pass filter 19 is configured to low pass filter the interpolated harmonics according to a second cutoff frequency thereof.

The delay unit 20 is configured to delay the audio input signal by a period of time. The second synthesizer 21 is configured to synthesize the delayed audio input signal and the low pass filtered harmonics from second low pass filter 19. The AGC 22 is configured to control a gain of the synthesized signal from the second synthesizer 21 automatically to produce an audio output signal. As a result, the harmonics of the fundamental frequency signal in the low frequency component of the audio input signal is enhanced. In other words, the bass of the audio signal is enhanced virtually.

In one embodiment, the first low pass filter 11 is identical to the second low pass filter 19 in functions. A simple low pass filter known to those skilled in the art may be used as the first low pass filter 11 or the second low pass filter 19. In general, the frequency under 1 khz of the audio signal includes almost all low frequency components. So, the cutoff frequency f_{c} of the first low pass filter 11 or the second low pass filter 19 should be no less than 1 khz. Additionally, the cutoff frequency f_{c} of the first low pass filter 11 or the second low pass filter 19 should be no larger than fₛ/2M in order to avoid aliasing, wherein fₛ, is a sampling frequency of the audio signal, and M is the down-sampling factor of the subsample unit 12.

In one embodiment, the subsample unit 12 is configured to pick out one sample from the low pass filtered frequency signal every M samples, and wherein M is the down-sampling factor herein. Correspondingly, the interpolation unit 18 is configured to insert M−1 zeros after each sample of the input signal sequence, wherein M is the interpolation factor herein. The down-sampling factor is same as the interpolation factor. The subsample unit 12 and the interpolation unit 18 are provided to reduce the data rate such that the T/F transformer 13 and the F/T transformer 17 work at the lower data rate, thereby the computing complexity is reduced significantly. In a preferred embodiment, M=8 is selected. In another embodiment, the subsample unit 12 and the interpolation unit 18 may not be necessary.

For example, if the sampling frequency of the audio signal is 44.1 KHz and M=8, the cutoff frequency f_{c} of the low pass filter should satisfy f_{c}≦44100/2/8, namely f_{c}≦2756 Hz. In a preferred embodiment, a 64-order FIR filter with the cutoff frequency of 1.5 KHz is used as the first low pass filter 11 or the second low pass filter 19.

In one embodiment, the T/F transformer 13 comprises an analysis window module and a Fast Fourier Transform (FFT) module. The analysis window module is configured to process the down sampled low frequency signal within a window predefined. The FFT module is configured to Fourier-transform the low frequency signal processed by the analysis window module to produce the low frequency signal in the frequency domain. The F/T transformer 17 comprises an Inverse Fast Fourier Transform (IFFT) module and an integrated window module. The IFFT module is configured to inverse-Fourier-transform the synthesized harmonics in the frequency domain into corresponding synthesized harmonics in the time domain. The integrated window module is configured process the synthesized harmonics in the time domain with window predefined.

The low frequency signal in the frequency domain from the T/F transformer 13 comprises a predefined number of frequency bands. The predefined number is related to FFT points of the T/F transformer 13, e.g., there are 128 frequency bands if the FFT points are 128. Each frequency band comprises a real part denoted as Real and an imaginary part denoted as Imag.

A phase Phase(i) of the ith frequency band is computed according to:

$$Phase ( i ) = arc tg ( \frac{Imag ( i )}{Real ( i )} ) ,$$

wherein Real(i) is the real part of the ith frequency band, Imag(i) is the imaginary part of the ith frequency band, and i is the sequence number of the frequency band.

Then, a phase difference Tmp between the phases of a current frame and a last frame of the ith frequency band is computed according to:

Tmp=Phase(i)−Phase_old(i),

wherein Phase(i) is a phase of the current frame of the ith frequency band, and Phase_old(i) is the phase of the last frame of the ith frequency band.

A standard phase difference TmpS of the ith frequency band is:

$$TmpS = 2 π ⋆ i ⋆ \frac{stepsize}{fftsize} ,$$

wherein stepsize is a step size of signal processing, and fftsize is FFT points. In general, stepsize is less than fftsize. In a preferred embodiment, stepsize is a quarter of fftsize.

Therefore a difference TmpD between the phase difference Tmp and the standard phase difference TmpS is:

TmpD=Tmp−TmpS,

The difference TmpD is normalized between −π and π to generate a normalized difference TmpD′. Then, a frequency deviation FreqD is computed according to:

$$FreqD = \frac{{TmpD}^{′}}{2 π} ⋆ M ⋆ FreqPerBin ,$$

wherein FreqPerBin is a bandwidth of each frequency band.

Thus, an accurate frequency FreqS(i) of the ith frequency band is computed according to:

FreqS(i)=i*FreqPerBin+FredD.

In general, the fundamental frequency of the low frequency signal is very low, e.g. under 80 Hz. Hence, only several frequency bands with minimum frequencies are provided to search the fundamental frequency signal. In one embodiment, if fₛ=44.1 KHz, M=8, and the FFT points is 258, the bandwidth of each frequency band is about 20 Hz. So, the fundamental frequency signal is searched in the four frequency bands with minimum frequencies.

An amplitude Magn(i) of the ith frequency band is computed according to:

Magn(i)=\sqrt{Real(i)*Real(i)+Imag(i)*Imag(i)}.

One frequency band F_i with maximum amplitude of the four frequency bands with minimum frequencies are selected according to:

F_{—}i=arg[Max(Magn(i))], i=0˜3.

Finally, the frequency F of the fundamental frequency signal is:

F=FreqS[F_i].

The amplitude of the fundamental frequency signal is:

MF=Magn[F_i].

As a result, the fundamental frequency signal is determined by the fundamental frequency detector 14.

In operation, a frequency of each harmonic is an integer multiple of the frequency F of the fundamental frequency signal. Therefore, the frequencies Fh(k) of the harmonics are:

Fh(k)=kF, k=1, 2, 3, 4, 5,

wherein k is a sequence number of the harmonic, and only five minimum harmonics are considered herein.

The amplitudes MFh(k) of the harmonics are:

MFh(k)=a(k)MF,

wherein a(k) is an amplitude proportional factor of the kth harmonic, and a(k) is a decimal larger than 0. Different harmonics have different amplitude proportional factors. In general, the higher the frequencies of the harmonics are, the smaller the amplitude proportional factors of the harmonics become.

Next it needs to compute an accurate phase Phase(k) of each harmonic. Provided that the frequency Fh(k) of the kth harmonic is located in the ith frequency band, a normalized difference FreqD between the frequency Fh(k) of the kth harmonic and the standard frequency of the ith frequency band is:

FreqD=(Fh(k)−i*FreqPerBin)/FreqPerBin.

A relative phase difference TmpD is computed according to:

$$TmpD = 2 π \frac{FreqD}{M} .$$

An accurate phase difference Tmp is obtained according to:

$$Tmp = TmpD + 2 π ⋆ i ⋆ \frac{stepsize}{fftsize} .$$

A final phase Phase(k) of the kth harmonic is computed according to:

Phase(k)=Tmp+Tmp_sum,

wherein Tmp_sum is an accumulated phase difference before the accurate phase difference Tmp. The accumulated phase difference Tmp_sum is updated according to Tmp_sum=Phase (k), wherein an initial value of the accumulated phase difference Tmp_sum is 0.

Finally, the real part of the kth harmonic is computed according to:

Real(k)=MF(k)*cos(Phase(k)).

The imaginary part of the kth harmonic is computed according to:

Imag(k)=MF(k)*sin(Phase(k)).

As a result, the harmonics are generated by the harmonic generator 15.

In one embodiment, the delay unit 20 is configured to delay the audio input signal by D samples, wherein D is a time delay value. The delay is designed to align the phases of the harmonics with the phase of the original audio input signal in order to avoid signal cancellation because of non-alignment. All possible delays during generating the final harmonics according to the audio input signal should be considered to determine the time delay value D. In one embodiment, provided that lengths of the first low pass filter 11 and the second low pass filter 19 are L and lengths of the analysis window and the integrated window are W, the time delay value D may be:

D=L/2*2+W/2*M,

wherein L/2 is a delay caused by one low pass filter, W/2 is a delay caused by the analysis window module and the integrated window module.

The AGC 22 is configured to enhance the volume of the bass under the condition that no saturation distortion happens to the audio signal. In one embodiment, the AGC 22 comprises a first gain unit, a second gain unit, an intra-frame smoothing unit and an output unit. The first gain unit is configured to determine a signal amplitude with maximum absolute value of a current frame of the synthesized audio signal, and compare the signal amplitude with a target threshold to produce a first gain value.

The second gain unit is configured to compare the first gain value with an old gain value used in a last frame of the synthesized audio signal, produce a second gain value equal to the first gain value when the first gain value is less than the old gain value, and produce the second gain value being a sum of the old gain value and a predefined step size when the first gain value is larger than the old gain value.

The intra-frame smoothing unit is configured to smooth the second gain value according to a slope function and the old gain value to produce a current gain value used in the current frame. The output unit is configured to amplify the synthesized audio signal according to the current gain value to produce an audio output signal.

For example, provided that the signal amplitude with maximum absolute value of the current frame of the synthesized audio signal is Vmax, and Ti is the target threshold which the signal amplitude of the audio output signal is desired to reach, the ideal gain value gain_t (namely the first gain value) of the current frame is:

gain_{—}t=Ti/Vmax.

Because that the gain control way of fast down and slow up is used in the AGC 22, the following operations are performed:

gain=gain_old, if gain_t<gain_old;

wherein gain_old is a final gain (namely the old gain value) of the last frame, gain is the second gain value, and a minimum value of the second gain value gain is a low threshold LowLimit;

gain=gain_old+step, if gain_t>gain_old;

wherein step is a step size during increasing the second gain value gain, a maximum value of the second gain value gain is a high threshold HighLimit.

Then, the second gain value gain is further intra-frame smoothed according to following formula:

gainW(i)=b(i)gain_old+(1−b(i))gain, i=0˜N−1;

wherein gainW(i) is the current gain value of the ith sample in the current frame, N is the number of samples in each frame, and b(i) is the slope function.

FIG. 2 is a diagram showing an example of the slope function b(i), wherein b(i)=1−i/N. It can be seen that the old gain value gain_old of the last frame is assigned with a larger weight and the second gain value gain of the current frame is assigned with a smaller weight at the beginning of the current frame. On the contrary, the old gain value gain_old of the last frame is assigned with a smaller weight and the second gain value gain of the current frame is assigned with a larger weight at the end of the current frame.

Finally, the AGC 22 is configured to amplify the audio signal input(i) according to the current gain value gainW(i) to produce the audio output signal output(i), wherein output(i)=input(i)*gainW(i), i=0˜N−1.

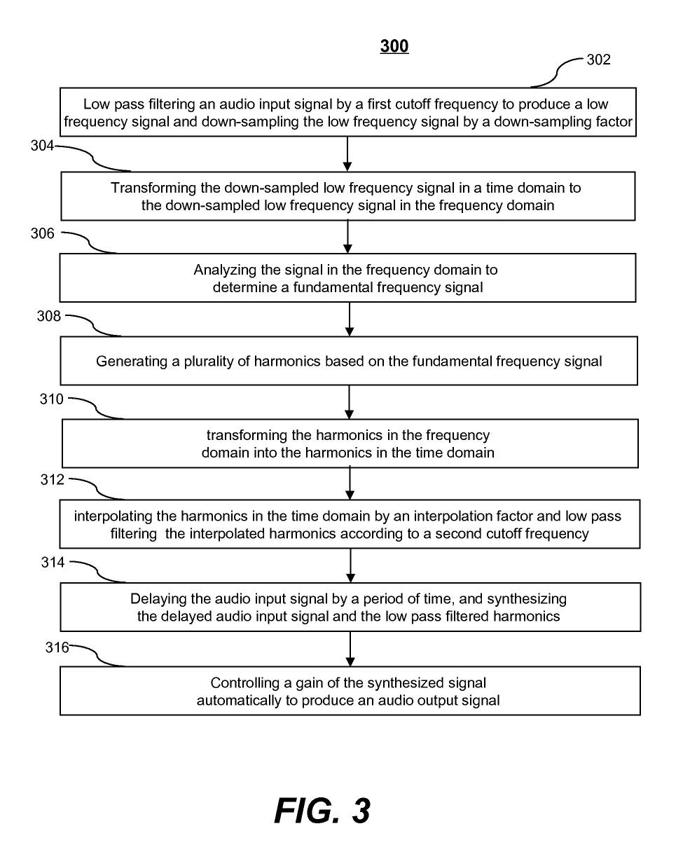

FIG. 3 is a flow chart showing a method 300 for virtual bass enhancement according to one embodiment of the present invention. FIG. 3 may be understood in accordance with FIG. 1 and FIG. 2.

At 302, an audio input signal is low pass filtered according to a first cutoff frequency and the low frequency signal is down sampled by a down-sampling factor. t 304, the down-sampled low frequency signal in a time domain is transformed to the down-sampled low frequency signal in the frequency domain. At 306, the down-sampled low frequency signal in the frequency domain is analyzed to determine a fundamental frequency signal.

At 308, a plurality of harmonics is generated based on the fundamental frequency signal. At 310, the harmonics in the frequency domain is transformed to the harmonics in the time domain. At 312, the harmonics in the time domain is interpolated by an interpolation factor and the interpolated harmonics is low pass filtered according to a second cutoff frequency. At 314, the audio input signal is delayed by a period of time and the delayed audio input signal and the low pass filtered harmonics are synthesized. At 316, a gain of the synthesized signal is controlled automatically to produce an audio output signal.

As a result, the harmonics of the fundamental frequency signal in the low frequency component of the audio input signal is enhanced. In other words, the bass of the audio signal is enhanced virtually.

In one embodiment, the operation of down sampling the low frequency signal and the operation of interpolating the harmonics may be not necessary.

The present invention has been described in sufficient details with a certain degree of particularity. It is understood to those skilled in the art that the present disclosure of embodiments has been made by way of examples only and that numerous changes in the arrangement and combination of parts may be resorted without departing from the spirit and scope of the invention as claimed. Accordingly, the scope of the present invention is defined by the appended claims rather than the foregoing description of embodiments.

What is claimed is:

1. A method for virtual bass enhancement, the method comprising:
low-pass filtering an audio input signal to produce a low frequency signal of the audio input signal;
transforming the low frequency signal from a time domain to a frequency domain;
determining a fundamental frequency signal of the low frequency signal in the frequency domain;
generating a plurality of harmonics based on the fundamental frequency signal;
transforming the harmonics from the frequency domain to the time domain; and
synthesizing the audio input signal and the harmonics to produce an audio output signal with bass enhancement.

2. The method according to claim 1, wherein the transforming the low frequency signal from a time domain to a frequency domain comprises:
processing the low frequency signal according to analysis windows; and
Fourier-transforming the processed low frequency signal from the time domain to the frequency domain.

3. The method according to claim 1, wherein the transforming the harmonics from the frequency domain to the time domain comprises:
inverse-Fourier transforming the harmonics from the time domain to the frequency domain; and
processing the harmonics in the time domain according to integrated windows.

4. The method according to claim 1, wherein the determining a fundamental frequency signal of the low frequency signal in the frequency domain comprises:
computing a frequency of each frequency band of the low frequency signal in the frequency domain;
computing an amplitude of each frequency band of the low frequency signal in the frequency domain;
selecting several frequency bands with minimum frequencies; and
determining one frequency band with maximum amplitude from the several frequency bands; and wherein the frequency of the determined frequency band is taken as a frequency of the fundamental frequency signal, and the amplitude of the determined frequency band is taken as an amplitude of the fundamental frequency signal.

5. The method according to claim 1, wherein the generating a plurality of harmonics based on the fundamental frequency signal comprises:
multiplying a frequency of the fundamental frequency signal by a plurality of integers to obtain frequencies of the harmonics, respectively;
multiplying an amplitude of the fundamental frequency signal by a plurality of proportional factors to obtain amplitudes of the harmonics, respectively; and
synthesizing the harmonics.

6. The method according to claim 1, further comprising:
down-sampling the low frequency signal by a down-sampling factor before the low frequency signal is transformed from the time domain to the frequency domain;
interpolating the harmonics in the time domain by an interpolation factor after the harmonics are transformed from the frequency domain to the time domain;
low pass filtering the interpolated harmonics before the harmonics are synthesized with the audio input signal; and wherein
the down-sampling factor is equal to the interpolation factor.

7. The method according to claim 1, further comprising:
delaying the audio input signal by a period of time before the audio input signal is synthesized with the harmonics.

8. The method according to claim 1, further comprising:
controlling a gain of the synthesized audio input signal automatically to produce the audio output signal with bass enhancement.

9. The method according to claim 1, wherein the controlling a gain of the audio output signal automatically comprises:
determining a signal amplitude with maximum absolute value of a current frame of the synthesized audio input signal;
comparing the determined signal amplitude with a target threshold to produce a first gain value;
comparing the first gain value with an old gain value used in a last frame of the synthesized audio input signal to produce a second gain value, the second gain value being equal to the first gain value when the first gain value is less than the old gain value, and the second gain value being a sum of the old gain value and a predefined step size when the first gain value is larger than the old gain value;
intra-frame smoothing the second gain value according to a slope function and the old gain value to produce a current gain value used in the current frame; and
amplifying the synthesized audio input signal according to the current gain value to produce the audio output signal.

10. A system for bass enhancement, comprising:
a first low pass filter configured to low pass filter an audio input signal to extract a low frequency signal from the audio input signal;
a subsample unit configured to down sample the low frequency signal according to a down-sample factor;
a T/F transformer configured to transform the down sampled low frequency signal from a time domain to a frequency domain;
a fundamental frequency detector configured to determine a fundamental frequency signal of the low frequency signal in the frequency domain;
a harmonics generator configured to generate a plurality of harmonics based on the fundamental frequency signal;
a F/T transformer configured to transform the harmonics from the frequency domain to the time domain;
an interpolation unit configured to interpolate zeros into the harmonics in the time domain according to an interpolation factor being equal to the down sample factor;
a second low pass filter configured to low pass filter the interpolated harmonics;
a delay unit configured to delay the audio input signal by a period of time;
a synthesizer configured to synthesize the delayed audio input signal and the low pass filtered harmonics; and
an AGC configured to control a gain of the synthesized signal automatically to produce an audio output signal with bass enhancement.

11. The system according to claim 10, wherein the AGC is configured to:
determine a signal amplitude with maximum absolute value of a current frame of the synthesized audio input signal;
compare the determined signal amplitude with a target threshold to produce a first gain value;
compare the first gain value with an old gain value used in a last frame of the synthesized audio input signal to produce a second gain value, the second gain value being equal to the first gain value when the first gain value is less than the old gain value, and the second gain value being a sum of the old gain value and a predefined step size when the first gain value is larger than the old gain value;
intra-frame smooth the second gain value according to a slope function and the old gain value to produce a current gain value used in the current frame; and
amplify the synthesized audio input signal according to the current gain value to produce the audio output signal.

12. The system according to claim 10, wherein the fundamental frequency detector is configured to:
compute a frequency of each frequency band of the low frequency signal in the frequency domain;
compute an amplitude of each frequency band of the low frequency signal in the frequency domain;
select several frequency bands with minimum frequencies; and
determine one frequency band with maximum amplitude from the several frequency bands; and wherein
the frequency of the determined frequency band is taken as a frequency of the fundamental frequency signal, and the amplitude of the determined frequency band is taken as an amplitude of the fundamental frequency signal.

13. The system according to claim 10, wherein the harmonics generator is configured to:
multiply a frequency of the fundamental frequency signal by a plurality of integers to obtain frequencies of the harmonics, respectively;
multiply an amplitude of the fundamental frequency signal by a plurality of proportional factors to obtain amplitudes of the harmonics, respectively; and
synthesize the harmonics.

14. A system for bass enhancement, comprising:
a T/F transformer configured to transform an audio signal from a time domain to a frequency domain;
a fundamental frequency detector configured to determine a fundamental frequency signal of the audio signal in the frequency domain;
a harmonics generator configured to generate a plurality of harmonics based on the fundamental frequency signal;
a F/T transformer configured to transform the harmonics from the frequency domain to the time domain;
a delay unit configured to delay the audio signal by a period of time;
a synthesizer configured to synthesize the delayed audio signal and the harmonics in the time domain.

15. The system according to claim 14, further comprising:
a AGC configured to control a gain of the synthesized signal automatically to produce an audio output signal with bass enhancement.
